(19) United States
(12) Patent Application Publication
(10) Pub. No.: US 2006/0193262 A1
(43) Pub. Date: Aug. 31, 2006

(54) Collecting and managing data at a construction site

(76) Inventors: Brendan T. McSheffrey, Newton, MA (US); Tod Riedel, Hingham, MA (US)

Correspondence Address: FISH & RICHARDSON PC, P.O. BOX 1022, MINNEAPOLIS, MN, 55440-1022, US

(21) Appl. No.: 11/066,066

(22) Filed: Feb. 25, 2005

(51) Int. Cl. H04L 12/26; H04M 11/04; H04Q 7/00; G01R 31/08; G08C 15/00; G06F 11/00; H04J 3/14; H04J 1/16; H04L 1/00

(52) U.S. Cl. 370/241; 370/328

(57) ABSTRACT

Data is collected at one or more construction sites using an array of wireless sensory devices distributed throughout each site. Data collected from the array of wireless sensory devices can be transmitted to a central gateway at the site, where it is forwarded to a remote server accessible over the Internet. A user, such as a general contractor in charge of the site or sites, can manually or automatically download sensory data to a client computer at any connection point to the Internet. The wireless sensory devices can be attached to identification badges carried by workers, pressure gauges on air compressors, tools used at the site, or other items at the site. The sensory devices can be used to monitor presence at the site, abnormal acceleration, position, pressure, or other predetermined conditions.

### TECHNICAL FIELD

This disclosure relates to collection and management of data at a construction site.

### BACKGROUND

Management of resources, such as tools, materials, and workers, at a construction site is often a significant concern of a general contractor charged with overseeing work at the site. In addition, a general contractor may be responsible for several construction sites and, therefore, must allocate resources efficiently across multiple sites. A system for tracking persons and items at multiple construction sites may assist a general contractor in more efficiently allocating resources.

### SUMMARY

In one aspect the invention features a system for collecting data at a construction site that includes a wireless network (e.g., a wireless mesh network) located at the construction site and a plurality of wireless sensory devices, each wireless sensory device attached to an item used at the construction site and configured to issue a signal indicating one or more predetermined conditions to a remote gateway using the wireless network.

Various aspects of the invention may include one or more of the following features. The predetermined conditions may include one or more of the following: presence of the wireless sensory device on the wireless network, a low battery condition of the wireless sensory device, a pressure reading of an air compressor or other pressurized container, or an acceleration of the wireless sensory device (e.g., to indicate whether a person or tool has fallen).

The wireless sensory device may include an accelerometer to monitor acceleration. The wireless sensory device may be attached to an identification card for a worker at the site or may be attached to a tool used at the construction site. The wireless sensory device may be configured to issue a signal upon detection of acceleration or deceleration above a predetermined amount.

The wireless sensory device may also be configured to issue a heartbeat signal indicating presence on the wireless network and operability of a battery powering the wireless sensory device.

The gateway may be a personal computer or a single-board computer such as a cellular telephone, personal data assistant, or other device. The gateway may in communication with and transfer data to a server of another network such as the Internet.

In another aspect, the invention features an apparatus for remote monitoring of an air compressor that includes a pressure gauge for monitoring air pressure within an air compressor and a wireless sensory device for issuing a wireless signal about the monitored air pressure to a remote device using a wireless network (e.g., a wireless mesh network).

Various aspects of the invention may include one or more of the following features. The wireless sensory device may be configured to issue a signal upon detection of an out-of-range pressure condition or may be configured to periodically issue a signal indicating a recent pressure reading. The wireless sensory device may be powered by a battery and may be further configured to issue a signal upon detection of a low battery condition. The wireless sensory device may also be configured to periodically issue a signal (e.g., a heartbeat signal) indicating presence of the device on the wireless network. This heartbeat signal may also be used to monitor battery condition.

In one particular implementation, the wireless may located at a construction site and the air compressor may be a portable air compressor.

In another aspect, the invention features a method that includes collecting data at one or more construction sites, the data including information about presence of items at a construction site, and presenting the data using a glanceable device (e.g., a light source or meter).

Various aspects may include one or more of the following features. Data may be transmitted to a server and accessed by a client device located remotely from the server. The client device may present the data on a glanceable device.

In another aspect, the invention features a method that includes enabling a user to subscribe to a periodically-updated stream of sensory data collected at one or more construction sites, receiving at a server new sensory data corresponding to the subscribed stream of sensory data, and notifying the user of new sensory data.

Various aspects of the invention may include one or more of the following features. Information (e.g., the new sensory data or a summary of the new data) may be posted at a designated Uniform Resource Locator indicating new sensory data received at the server. Notification of the used of new sensory data may be accomplished using Really Simple Syndication (RSS).

The periodically-updated stream of sensory data may include data indicating presence of persons at one or more construction sites, operation of one or more air compressors used at a construction site, or operation of one or more tools at a construction site.

Other features, objects, and advantages will be apparent from the description and drawings, and from the claims.

### DESCRIPTION OF DRAWINGS

FIG. 1 is a diagram of a system for collecting and managing data at a construction site.

FIG. 2 is a diagram of wireless sensory devices communicating with a gateway using a wireless network.

FIG. 3A is a diagram of a portable air compressor.

FIGS. 3B-3C are a front and rear view, respectively, of a gauge used on a portable air compressor.

FIG. 4 is a diagram of a wireless network at a construction site.

FIGS. 5 and 6 are diagrams of systems for accessing sensory data collected from one or more construction sites.

### DETAILED DESCRIPTION

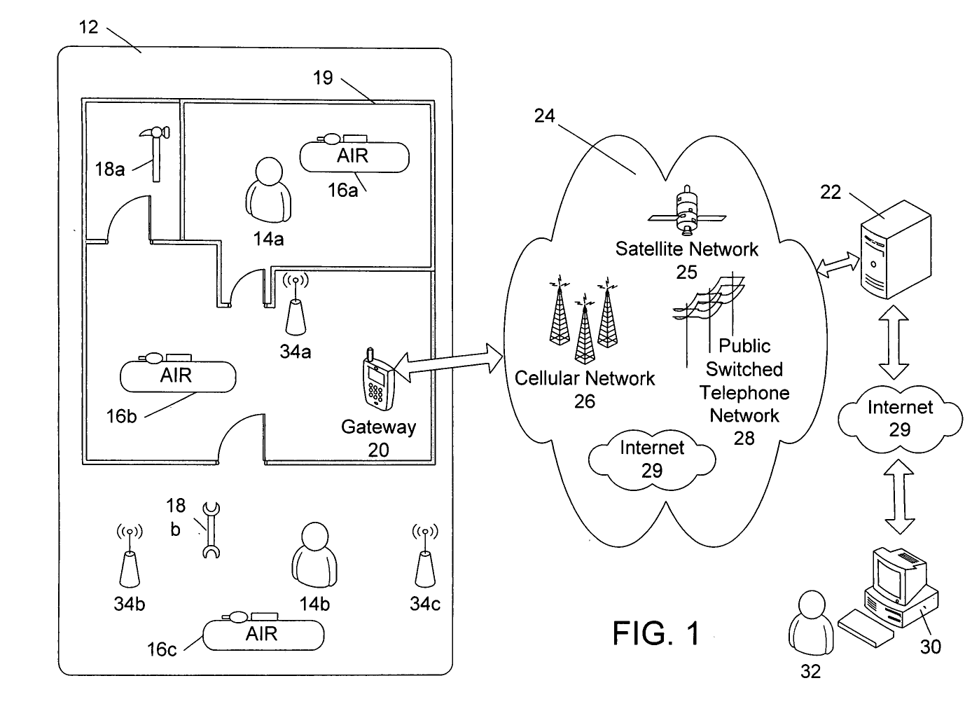

Referring to FIG. 1, a system 10 for tracking persons and items on a construction site 12 includes wireless sensory devices (not shown) carried by persons or attached to items, e.g., persons 14a, 14b, portable air compressors 16a-16c, and tools 18a-18b, that are in communication with a gateway 20 using a wireless local area network (LAN). The wireless LAN includes several nodes 22a-22c dispersed throughout the construction site 12 that link the wireless sensory devices with the gateway 20.

The wireless sensory devices carried by persons or attached to items at the construction site are configured to sense predetermined conditions, such as presence of the sensory device on the wireless LAN, location of the sensory device within the mesh network, abnormal acceleration/deceleration of the sensory device (indicating, for example, a dropped item), a pressure reading (e.g., of a portable air compressor which indicates, for example, usage of the air compressor), a battery condition of the sensor, temperature, humidity, presence of an obstruction blocking viewing of or access to a device, or detection of a gas such as carbon monoxide. Information from the array of sensory devices dispersed throughout the construction site is forwarded by the gateway 20 to a server 22 through a communication medium 24, such as a satellite network 24, cellular network 26, public switched telephone network (PSTN) 28, a computer network such as the Internet 29, or a paging network (not shown).

Sensory data stored on the server 22 can be accessed remotely over the Internet 29, for example, by a general contractor 32 responsible for the construction site using a personal computer 30 or other computing device (e.g., a personal data assistant (PDA), laptop computer, cellular telephone, etc.). In some implementations, select sensory data forwarded to the server is automatically pushed to a remote user, for example, using Really Simple Syndication (RSS) or Extensible Markup Language (XML) protocol.

By collecting sensory data about items and persons at a construction site, a general contractor or other user can track inventory, employees, and subcontractors at the construction site. In addition, a general contractor can track usage of tools, equipment and other resources at the construction site, and, identify when such resources are being under or over utilized. A general contractor can also remotely monitor the construction site for accidents (e.g., a person falling) or incidents that require attention (e.g., a sensitive tool has been dropped and likely need re-calibration or a tracked item loses contact with the wireless LAN during non-working hours indicating a possible theft). Moreover, by use of wireless LANs at multiple construction sites, a general contractor can assess utilization of resources across multiple projects. In addition, sensory data collected at one or more construction sites can be analyzed in the aggregate to identify, for example, when resources at a particular site are generally being over or under utilized.

The wireless LAN includes several wireless nodes 34a-34c that can be interconnected in any known network topology, such as a mesh, partial mesh, bus, star or tree topology. The wireless LAN can be any known wireless LAN, such as a ZigBee™ wireless mesh network or other an IEEE 802.15.4-compliant wireless network or a Bluetooth-compliant wireless network or other IEEE 802.11-compliant wireless network. In a Zigbee network, wireless sensory devices may be Reduced Function Devices (RFD), Full Function Devices (FFD), or Coordinators.

As illustrated in FIG. 1, some nodes of the wireless mesh network, e.g., nodes 34a-34c, are located inside a building 19 while others are located outside and are subject to the environment. The nodes, especially those located outside the building, are preferably housed in rugged, all-weather housing. In an IEEE 802.15.4 network, the nodes may be implemented as wireless repeaters, and in an IEEE 802.11 network, the nodes may be implemented as wireless routers. In some implementations, the nodes are powered by battery, and in these implementations, it is generally preferred to use an IEEE 802.15.4 wireless network, which is designed to consume low amounts of power. In some implementations, the nodes are powered by AC power supplied by, for example, a portable generator or a connection to a public power supply.

Gateway 20 includes a transreceiver for receiving data from and transmitting data to the array of wireless sensory devices located on the wireless LAN. Gateway 20 also includes one or more devices for transmitting sensory data to the server 22 using one or more communication media. For example, the gateway 20 may be equipped with a cellular modem, satellite modem, PSTN modem, and/or networking card transmitting data to the server. The gateway 20 may be implemented, for example, as a laptop computer, desktop computer, or a single-board computer (e.g., cellular telephone, PDA, etc.).

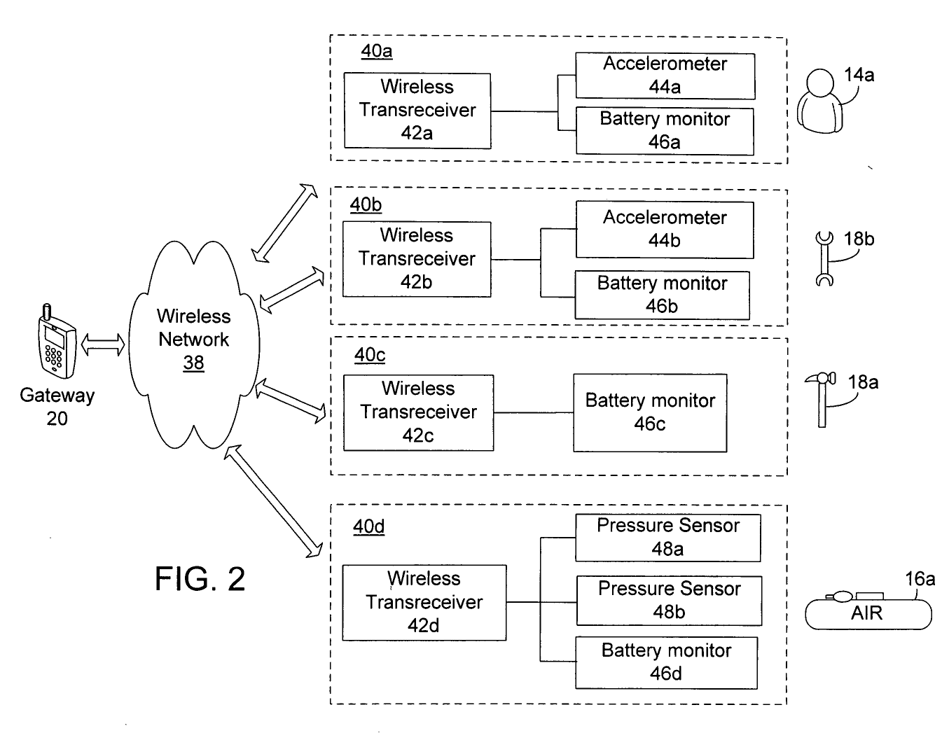

Referring to FIG. 2, persons and items at the construction site, e.g. person 14a, tool 18b, and air compressor 16a includes a wireless sensory device 40a-40d for communicating conditions with the gateway 20. Each wireless sensory device generally includes one or more sensor circuits and a miniature transreceiver device, such as EM2420 radio transreceiver manufactured by Ember Corporation (www.ember.com). The miniature transreceiver device 42a includes a radio-frequency (RF) transreceiver, programmable microprocessor, and battery.

Persons at the construction site, such as person 14a, carries with him or her a wireless sensory device 40a that includes an RF transreceiver 42a, an accelerometer 44a, and a battery monitor 46a. The accelerometer can be any miniature accelerometer device, such as 1, 2, or 3-axis accelerometer, configured to constantly monitor acceleration of the wireless sensory device (along one, two, or three axes). If the accelerometer detects an acceleration or deceleration above a predetermined amount, indicating, for example, that the person has fallen, the wireless sensory device 40a will transmit a signal to the gateway 20, which is in turn relayed to the server 22 (shown in FIG. 1). The wireless sensory device 40a also includes a battery monitor 46a, which monitors the condition of the device battery. If the battery monitor detects a low battery condition, the wireless sensory device 40a will transmit a signal to the gateway indicating a low battery condition. In some implementations, the wireless sensory device 40a carried by persons at the construction site are incorporated within an identification badge carried by authorized personnel (e.g., employees, sub-contractors, site owners, etc.). In addition to detecting if an item has dropped, an accelerometer can also be used to detect the relative position of an item. For example, a properly positioned accelerometer can detect whether a tool (e.g., a hammer) is lying on its side, positioned straight up, or is upside down. From this information, it can be determined whether the tool is being used.

The programmable microprocessor (not shown) of the wireless transreceiver device 40a is programmed to periodically (e.g., every 30 seconds) transmit a heartbeat signal to the gateway which indicates that the wireless sensor device is on the wireless LAN and operational.

Some tools, such as tool 18b shown in FIG. 2, include a wireless sensory device 40b that, like wireless sensory device 40a carried by person 14a, includes a wireless transreciever device 42b, accelerometer 44b, and a battery monitor 46b. Other tools, such as tool 18a, include a wireless sensory device 40c that includes only a wireless transreceiver device 40c and a battery monitor 46c. By including an accelerometer in certain tools, a general contractor or other user can be made aware of when a sensitive tools is dropped and needs adjustment (e.g., calibration). Data from an accelerometer may also be used to determine whether a tool is in a correct position, e.g., for storage. Similarly, by including a wireless sensory device 40b, 40c on tools 18a, 18b, a contractor is able to track tools as they are carried on and off the construction site. As in the wireless sensory device 40a carried by person 14a, the wireless sensory devices 40b, 40c affixed to tools 18a, 18b include a battery monitor 46b, 46c that causes the wireless transreceiver 42b, 42c to transmit a signal to gateway 20 upon detection of a low battery condition. Additionally, the wireless sensory devices 40b, 40c are programmed to periodically transmit a heartbeat signal to gateway 20.

Portable air compressor 16a includes a wireless sensory device 40d with wireless transreceiver device 42d, two pressure sensors 48a-48b, and battery monitor 46d. Like other wireless sensory devices 40a-40c, the battery monitor 46d is configured to cause the wireless transreceiver device 40d to transmit a signal to gateway 20 upon detection of a low battery condition. Similarly, the wireless sensory device 40d is configured to periodically transmit a heartbeat signal to the gateway indicating both presence on the wireless network and functionality of the wireless sensory device.

The two pressure sensors 48a-48b are configured to detect pressure conditions of the portable air compressor. One pressure sensor 48a monitor pressure of the air stored in a tank of the portable air compressor. If, for example, the pressure of the portable air compressor indicates that the air compressor is operational (e.g., a pressure reading of over 90 psi), then the pressure sensor 48a causes the wireless transreceiver 42d to transmit a signal to the gateway 20 indicating that the air compressor is being used. If, however, the pressure sensor 48a detects that the pressure of the portable air compressor indicates that it is not operational (e.g., pressure is zero), then the pressure sensor causes the wireless transreciever 42d to transmit a signal to the gateway 20 indicating the compressor is not being used.

The other pressure sensor 48b monitors pressure of air being delivered to an air tool via an outlet to the compressor. If, for example, the pressure of air being delivered via the outlet indicates that an air tool is connected to the outlet (e.g., a pressure reading of 90 psi), then the pressure sensor 48b causes the wireless transreceiver 42d to transmit a signal to the gateway 20 indicating that an air tool is connected to the compressor. If, however, the pressure of air being delivered via the outlet indicates than an air tool is not connected to the outlet (e.g., the pressure is zero), then the pressure sensor 48b causes the wireless transreceiver 42d to transmit a signal to the gateway 20 indicating that an air tool is not connected to the compressor.

By monitoring the air in the tank and/or delivered via the outlet of one or more portable air compressors on a construction site, a contractor or other user can determine if portable air compressors are being under or over utilized at the construction site. If compressors are being under utilized, then a contractor may move one or more compressors to other construction sites where compressors appear to be over utilized. In this way, a contractor is able to more efficiently manage its resources.

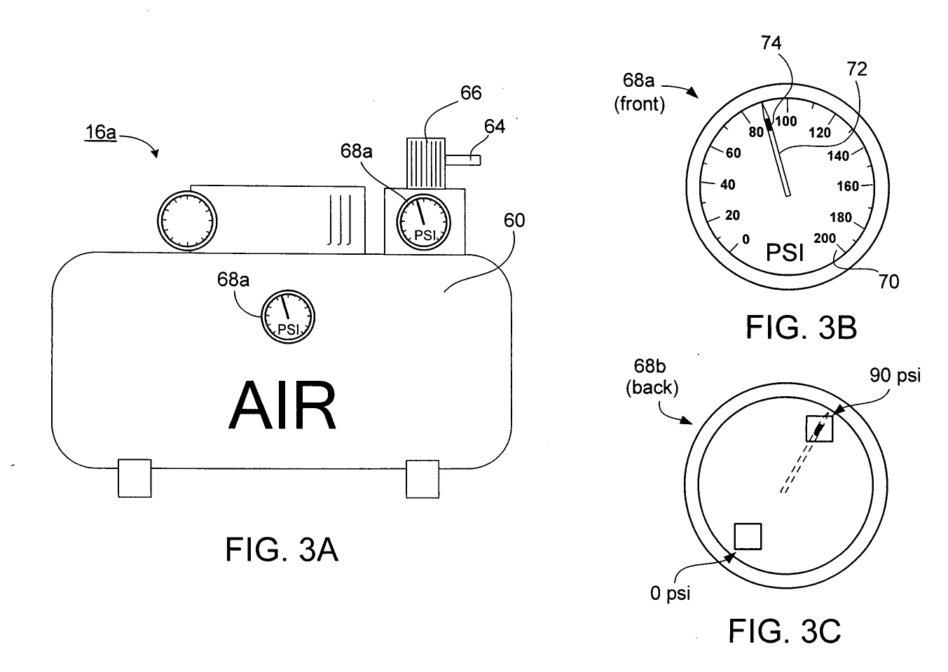

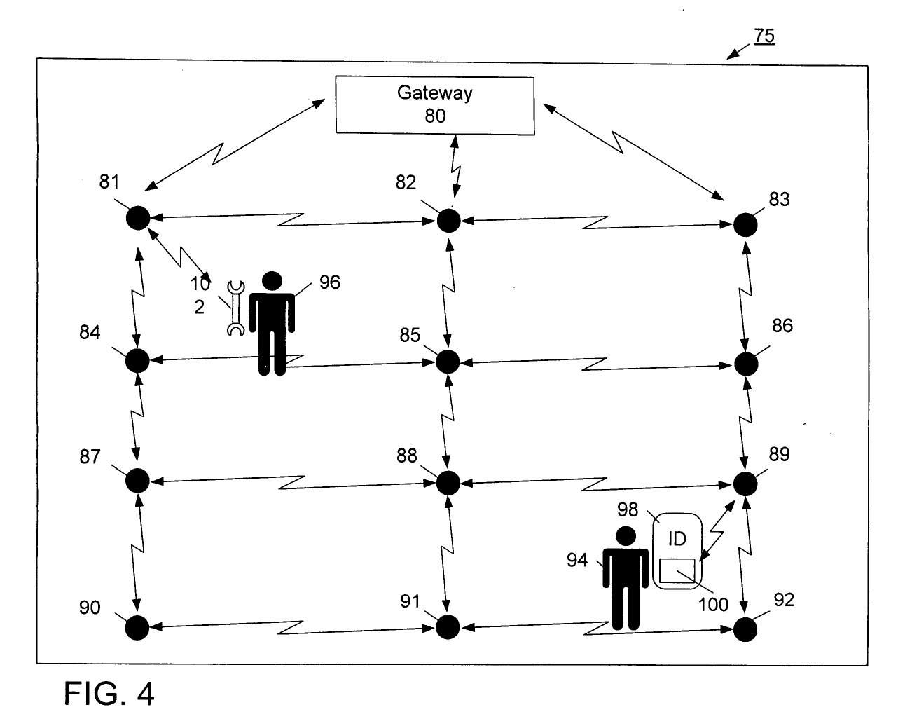

In some implementations, a pressure sensor may comprise a Hall effect sensor mounted to a conventional pressure gauge. For example, referring to FIG. 3A, a portable air compressor 16a includes a tank 60 for holding compressed air and a motor 62 for drawing in and compressing air within the tank 60. The air compressor 16a also includes an outlet 64 and knob 66 for adjusting pressure of air that is delivered via the outlet 64. Two pressure gauges 68a, 68b respectively monitor the pressure of air within the tank and the pressure of air delivered via the outlet 64. The pressure gauges 68a, 68b may be any known gauge suitable for measuring pressure of air in an air compressor tank.

Each pressure gauge, e.g., gauge 68a shown in FIGS. 3B-3C, includes a gauge scale 70 and a needle 72, which indicates the pressure reading on the gauge scale. Attached to the distal end of the needle 72 is a small magnet 74. On the back side of the gauge scale 72 of pressure gauge 68a are two Hall effect sensors 76a, 76b, which are positioned respectfully at around zero PSI (pounds per square inch) and 90 PSI. Each Hall effect sensor is adapted to respond to proximity of the magnet 74 mounted to the needle 72 by initiating a signal to the wireless transreceiver device 42d (shown in FIG. 2). Thus, by using one or more Hall effect sensors on a pressure gauge, the wireless sensory device 40d is able to detect pressure conditions of the compressor tank and/or outlet valve.

In some implementations, a pressure sensor for a portable air compressor may comprise a pressure transducer, a giant magnetoresistive sensor (GMR), or other known sensor for converting a pressure reading into an electrical signal.

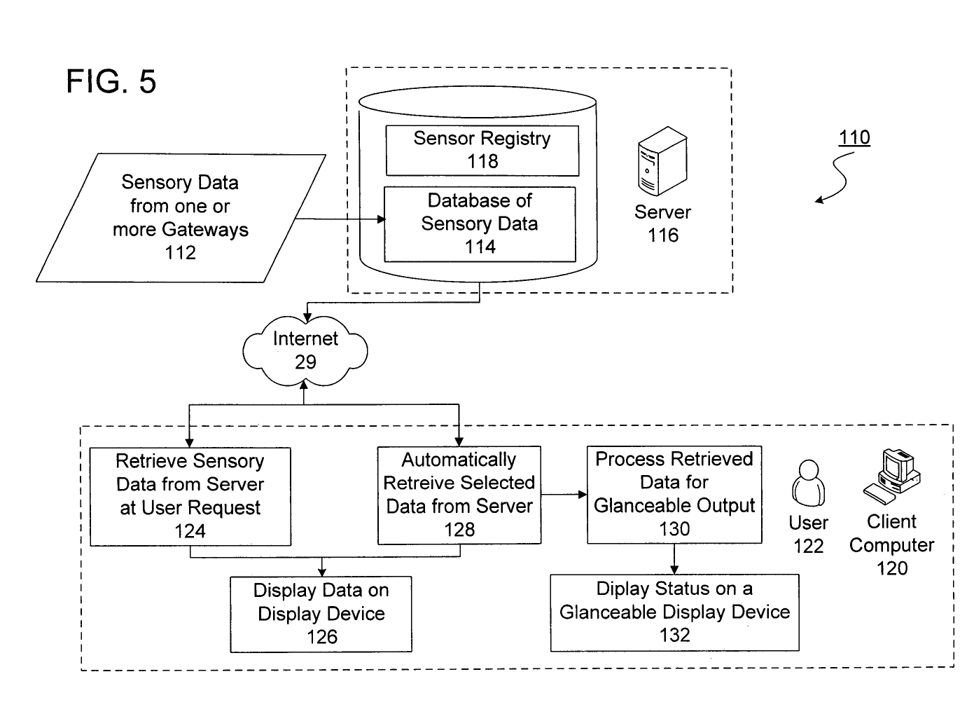

Referring to FIG. 4, an IEEE 802.15.4-compliant wireless mesh network 75 includes, for example, twelve (12) wireless repeaters 81-92 that are distributed in a grid pattern over a construction site. The wireless repeaters may be mounted atop a post protruding from the ground at a construction site and/or on a wall, ceiling, or floor of a building at the construction site. Besides using a grid system, the wireless repeaters may be distributed in other geographical arrangements (e.g., a spiral distribution, concentric circle distribution, linear or pipeline distribution, etc.) to provide different resolving granularity for localizing a wireless sensory device that initiates a signal to the gateway. A distribution pattern, such as the grid pattern shown in FIG. 4, may be illustrated as part of the plans and drawings that are used by workers at the construction site to construct the building or other structure at the site. A computer-aided drawing (CAD) program or similar software program may be programmed to automatically overlay a pattern of wireless repeaters on a site plan.

Person 94 carries with her an identification badge 98 that includes an embedded wireless sensory device 100. Upon entering the wireless network, the wireless sensory device 100 transmits a signal to one of the wireless repeaters that includes information sufficient to identify the wireless sensory device as well as the time at which the signal was received by the wireless mesh network. The signal is repeated across the nodes of the wireless mesh network until it reaches the gateway 80, where it is decoded and transmitted to a central server for storage. Similarly, tool 102 carried by person 96 is equipped with a wireless sensory device (not shown), and when the tool is carried onto mesh network 75, the wireless sensory device affixed to the tool transmits a signal to one of the repeaters that includes information sufficient to identify the wireless sensory device and the time at which the signal is transmitted to the wireless mesh network. The signal is then propagated across the mesh network to the gateway, where it is decoded and transmitted to a central server for storage. As the person 94 or 96 moves across the wireless mesh network, additional signals transmitted by the wireless sensory devices, are similarly propagated through the wireless mesh network to the gateway 80.

If a sensory device, e.g., sensory device 100, is equipped with an accelerometer and the accelerometer detects a rapid acceleration or deceleration above a predetermined amount (e.g., ˜3.8 m/s^{b 2}), the wireless sensory device is programmed to transmit a signal indicating a rapid acceleration/deceleration, an identification code associated with the wireless sensory device, and the time at which the acceleration/deceleration was detected. This signal is received on and propagated through the mesh network to the gateway.

Similarly, if a sensory device equipped with a battery monitor detects a low battery condition (e.g., the voltage supplied by the battery falls below a predetermined threshold), the wireless sensory device is programmed to transmit a signal indicating a low battery condition, an identification code associated with the wireless sensory device, and the time at which the low battery condition was detected. This signal is received on and propagated through the mesh network to the gateway.

Finally, if a wireless sensory device is equipped with a pressure sensor, the wireless sensory device is programmed to periodically (e.g., every 30 seconds) generate and transmit a signal indicating a current pressure condition, an identification code associated with the wireless sensory device, and the time at which the pressure condition was sensed. In other implementations, a wireless sensory device equipped with a pressure sensor is programmed to transmit a signal indicating a pressure condition only upon detection of a predetermined pressure condition (e.g., a pressure reading above and/or below certain amounts).

To associate wireless sensory devices, e.g., wireless sensory device 100, with a particular person or item, an owner of the wireless mesh network 75 (e.g., a general contractor) creates a sensor registry by entering information into a data table or other data structure that correlates a unique identification code associated with each wireless sensory device with a person or item. Thus, when the gateway, central server, or other device receives a signal with an identification code associated with a wireless sensory device, the person or item associated with the device can be determined by looking up the code in the sensor registry. Data may be entered into the sensor registry through an input device associated with the gateway, the central server, or a device in communication with the wireless mesh network and/or the central server. The sensor registry may be stored on the gateway, the central server, or on another device in communication with the wireless mesh network and/or the central server.

In some implementations, the wireless mesh network 75 is configured to track the location of persons and items within the mesh network by recording the repeater which first receives a signal transmitted by a wireless sensory device. Thus, for example, if repeater 89 first records a signal transmitted by wireless sensory device 100 embedded on ID badge, the wireless repeater 89 would include information identifying itself as the first node in a signal propagated to the gateway 80. In this way, movement of a person or item on the construction site is tracked. Accordingly, if a tool, person or other item on the construction site is missing, a general contractor or other user can query a database of stored sensory data to determine persons present on a construction site or at a particular area on a construction site when the tool, person or other item went missing. In addition, the wireless repeaters may include a signal strength indicator (e.g., Radio Signal Strength Indicator (RSSI), which can be used to determine the approximate location of a tool, person or other item within the grid of repeaters. Similarly, if a tool or other tracked item on the construction site ceases transmission of its heartbeat signal during non-work hours at the construction site (e.g., at night or on the weekends), the gateway and/or server may be programmed to send a notification to the general contractor and/or the police indicating a possible theft at the construction site.

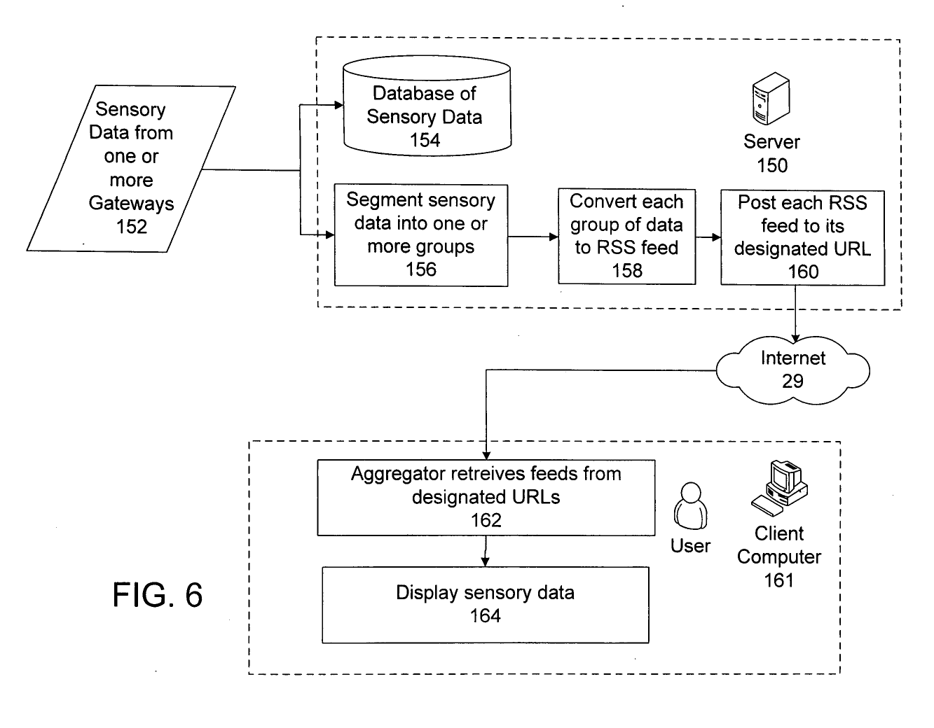

Referring to FIG. 5, a system 110 for delivering sensory data to a user 122 is shown. In this system, sensory data (112) from multiple gateways (e.g., gateway 80 shown in FIG. 4) at one or more construction sites is stored in a database (114) on a server 116 accessible via the Internet 29. In addition to the database of stored sensory data, the server 116 also stores sensor registry 118 which is a data table or other data structure that correlates wireless sensory devices to items and persons.

At a client computer 120, a user 122 can retrieve 124 sensory data stored on the server and display 126 the retrieved data on a display device such as a monitor. For example, if a contractor wants to view the status of all air compressors on every one of his construction sites, the contractor can query and download the latest sensory data on all air compressors at every construction site. Similarly, if a contractor wants to see if a particular employee is on one of the construction sites, the contractor can query and download sensory data for a card carried by a particular user.

In addition to permitting a user to query and download sensory data, computer 120 also includes software 128 that automatically retrieves selected sensory data from the server. For example, software 128 can be configured by the user to download all or only certain subsets of sensory data at variable frequency (e.g., every 30 minutes).

In some implementations, a server receiving sensory data from one or more construction sites can be configured to “push” data to a remote user. For example, as shown in FIG. 6, a server 150 receives sensory data 152 from one or more construction sites. As new sensory data is received from a gateway, the server 150 stores the data in a database 154 and segments the sensory data into one or more groups. The server may, for example, segment the sensory data according to the job site from which the data originated or type or sensory data (e.g., sensory data from persons, air compressors, specific tools, or all tools). Each group sensory data is then converted 158 into an RSS feed. The RSS feed is then posted 160 to a predetermined Universal Resource Locator (URL), which is subscribed to by an aggregator program running on user computer 161. The aggregator program downloads the RSS feeds from the appropriate URLs and displays 164 the new sensory data on a display (e.g., a monitor).

As the number of monitored construction sites and person/items on those sites increases, it becomes more difficult for a person to assimilate the monitored data. To help manage the large volume of sensory data stored at server 116, computer 120 also includes software that processes 130 retrieved data for output to a glanceable display such as an Ambient Orb™ or Ambient Dashboard™ by Ambient Devices (www.ambientdevices.com). A glanceable device is a device, such as a light source, meter, or sound source, which communicates information without demanding a user's attention. For example, sensory data on air compressors could be processed for output to a glanceable display such that the more air compressors are being used at a site (as indicated by a high pressure reading in the tank and/or outlet valve) causes a light to glow more green in color whereas the less air compressors are being used at a site causes a light to glow more red. Similarly, sensory data on workers at the site could be processed for output to a glanceable device such that relatively more workers present on the job site causes a needle to move towards one end of a scale whereas relatively less workers present causes the needle to move towards an opposite end of the scale. In this way, sensory data collected at a site can be analyzed in the aggregate in a simple, easy-to-view format.

A number of embodiments have been described. Nevertheless, it will be understood that various modifications may be made without departing from the spirit and scope of the invention. For example, additional logic can be employed at the gateway, the server, and/or client side to filter certain sensory data, e.g., sensory data indicating that a job site item is in a “normal” state (an air compressor is operational, a person is at the job site, a tool is being used, etc.). Accordingly, other embodiments are within the scope of the following claims.

What is claimed is:

1. A system for collecting data at a construction site, the system comprising:
a wireless network located at the construction site;
a plurality of wireless sensory devices, each wireless sensory device attached to an item used at the construction site and configured to issue a signal indicating one or more predetermined conditions to a remote gateway using the wireless network.

2. The system of claim 1 wherein a predetermined condition comprises presence of the wireless sensory device on the wireless network.

3. The system of claim 1 wherein a predetermined condition comprises a low battery condition of the wireless sensory device.

4. The system of claim 1 wherein the plurality of wireless sensory devices comprises:
a wireless sensory device configured to monitor air pressure of an air compressor located at the construction site.

5. The system of claim 4 wherein the wireless sensory device configured to monitor air pressure is configured to issued a signal upon detection of a predetermined pressure reading.

6. The system of claim 1 wherein the plurality of wireless sensory devices comprises:
a wireless sensory device configured to monitor acceleration.

7. The system of claim 6 wherein the wireless sensory device configured to monitor acceleration is attached to an identification card for a worker at the construction site.

8. The system of claim 6 wherein the wireless sensory device configured to monitor acceleration is attached to a tool used at the construction site.

9. The system of claim 6 wherein the wireless sensory device configured to monitor acceleration is configured to issue a signal upon detection of acceleration or deceleration above a predetermined amount.

10. The system of claim 1 wherein each wireless sensory device is configured to periodically issue a heartbeat signal indicating presence on the wireless network.

11. The system of claim 1 wherein the wireless network comprises a wireless mesh network.

12. The system of claim 1 wherein the gateway comprises a personal computer.

13. The system of claim 1 wherein the gateway comprises a single-board computer.

14. The system of claim 1 wherein the gateway is in communication with a server over a second network.

15. The system of claim 14 the gateway is configured to transmit information related to the wireless sensory devices to the server.

16. The system of claim 15 wherein the server is accessible via the Internet.

17. An apparatus for remote monitoring of an air compressor, the apparatus comprising:
a pressure gauge for monitoring air pressure within an air compressor; and
a wireless sensory device for issuing a wireless signal about the monitored air pressure to a remote device using a wireless network.

18. The apparatus of claim 17 wherein the wireless sensory device is configured to issue a signal upon detection of an out-of-range pressure condition.

19. The apparatus of claim 17 wherein the wireless sensory device is configured to periodically issue a signal indicating a recent pressure reading.

20. The apparatus of claim 17 wherein the wireless sensory device is powered by a battery and is further configured to issue a signal upon detection of a low battery condition.

21. The apparatus of claim 17 wherein the wireless sensory device is further configured to periodically issue a signal indicating presence of the device on the wireless network.

22. The apparatus of claim 17 wherein the wireless network is located at a construction site.

23. The apparatus of claim 17 wherein the wireless network is a wireless mesh network.

24. The apparatus of claim 17 wherein the air compressor comprises a portable air compressor.

25. A computer-implemented method comprising:
collecting data at one or more construction sites, the data including information about presence of items at a construction site; and
presenting the data using a glanceable device.

26. The method of claim 25 wherein the glanceable device comprises a light source.

27. The method of claim 25 wherein the glanceable device comprises a meter.

28. The method of claim 25 further comprising:
transmitting the collected data to a server.

29. The method of claim 28 wherein presenting data using a glanceable display comprises:
receiving the collected data from the server at a client device located remotely from the server; and
using the client device to present the data on a glanceable device.

30. A computer-implemented method comprising:
enabling a user to subscribe to a periodically-updated stream of sensory data collected at one or more construction sites;
receiving at a server new sensory data corresponding to the subscribed stream of sensory data; and
notifying the user of new sensory data.

31. The method of claim 30 wherein notifying the user of sensory data comprises:
posting information at a designated Uniform Resource Locator indicating new sensory data received at the server.

32. The method of claim 31 wherein posting information at a designated Uniform Resource Locator comprises posting the new sensory data received at the server.

33. The method of claim 31 wherein posting information at a designated Uniform Resource Locator comprises posting a summary of the new sensor data received at the server.

34. The method of claim 30 wherein notifying the user of new sensory data comprises:
using Really Simple Syndication to notify said user of new sensory data.

35. The method of claim 30 wherein the periodically-updated stream of sensory data comprises data indicating presence of persons at one or more construction sites.

36. The method of claim 30 wherein the periodically-updated stream of sensory data comprises data indicating operation of one or more air compressors used at a construction site.

37. The method of claim 30 wherein the periodically-updated stream of sensory data comprises data indicating operation of one or more tools at a construction site.
